(19) United States
(12) Patent Application Publication
(10) Pub. No.: US 2026/0282422 A1
(43) Pub. Date: Sep. 17, 2026

(54) HIGH BREAKDOWN VOLTAGE HEMT DEVICE AND DRIVING METHOD THEREOF

(71) Applicant: GaNexus Semiconductor (Shanghai) Ltd., Shanghai (CN)

(72) Inventor: TAO JIANG, Xi'an (CN)

(21) Appl. No.: 19/678,373

(22) Filed: May 15, 2026

Related U.S. Application Data
(63) Continuation of application No. PCT/CN2024/132074, filed on Nov. 14, 2024.

(30) Foreign Application Priority Data
Nov. 16, 2023 (CN) 202311533418.4

(51) Int. Cl. H10D 30/47; H10D 62/85

(52) U.S. Cl. CPC H10D 30/476; H10D 30/475; H10D 62/8503

(57) ABSTRACT

A high breakdown voltage HEMT device includes: a multilayer body material layer; a source electrode and a drain electrode stacked with the multilayer body material layer, a first gate electrode, and a second gate electrode. Along a first direction, the source electrode and the drain electrode are respectively located on opposite sides of the multilayer body material layer, or, the source electrode and the drain electrode are located on the same side of the multilayer body material layer and respectively disposed on different mesas. The first gate electrode is located on the same side of the multilayer body material layer as the source electrode and is adjacent to the source electrode. The second gate electrode is located on the same side of the multilayer body material layer as the first gate electrode, the first gate electrode is located between the second gate electrode and the source electrode.

### TECHNICAL FIELD

The disclosure relates to the field of microelectronic technologies, and more particularly to a high breakdown voltage high electron mobility transistor (HEMT) device and a driving method thereof.

### BACKGROUND

HEMT devices are planar devices in which a source electrode and a drain electrode are both located on a same plane. Therefore, the breakdown voltage capability of the material cannot be fully utilized. When a higher breakdown voltage of the device is required, only a physical distance between the source electrode and the drain electrode can be increased, which increases a chip area. On one hand, this increases costs, and on the other hand, decreases chip fabrication yield. In addition, due to limitations of substrate and buffer layer materials, the breakdown voltage of the device is difficult to increase to a particularly high level. A vertical device has an advantage that the source electrode and the drain electrode can be respectively disposed on two opposite sides of a body material, such that the body material bears a voltage between the source electrode and the drain electrode, thereby improving the breakdown voltage of the device. At the same time, integration density can also be improved, thereby obtaining a chip having a greater current density.

Existing gallium nitride (GaN)-based vertical devices are generally classified into two types, namely, planar-gate devices and vertical-gate devices. In the planar-gate device, a gate electrode parallel to a chip surface is used to control current. The source electrode and the gate electrode of the device are located in a same plane, while the source electrode and the drain electrode are located on different planes or on opposite sides of a device material layer. A current blocking layer covering a partial region is disposed between the source electrode and the drain electrode. In this case, a current conduction path generally extends from the drain electrode vertically through the body material via a region not covered by the current blocking layer toward a region on the chip surface covered by the gate electrode where the source electrode and the gate electrode are located, and then extends along a direction parallel to the planar gate electrode on the chip surface for a certain distance to reach the source electrode. An advantage of the planar gate electrode is that the gate fabrication process is relatively mature and simple. However, when the planar gate electrode is fabricated in a HEMT device structure, it is necessary to form, by ion implantation or other means, a current blocking layer in a material below a two-dimensional carrier gas channel in a region not covered by the gate electrode, i.e., a region not controlled by the gate electrode. Alternatively, during epitaxial growth of the device, growth of a current blocking layer is inserted, and then a portion of the material of the current blocking layer is removed by etching, followed by secondary epitaxy to continue growth of subsequent material layers. In this manner, a current path is formed that includes vertically passing through a region not covered by the current blocking layer and, after reaching a region on the chip surface covered by the gate electrode, horizontally flowing toward the source electrode. Whether the current blocking layer is formed by ion implantation or by a secondary epitaxial process, the related process is difficult and adversely affects material quality of the device. In addition, because there is no inversion channel layer to protect the gate electrode, gate degradation and significant leakage current are likely to occur under a long-term high electric field environment.

The vertical-gate device obtains a gate electrode by etching holes perpendicular to a chip device surface through different material layers, forming an insulation layer on inner walls of the holes, and then filling the holes with metal. A channel region controlled by the gate electrode is a body material layer, and application of a gate voltage causes sidewalls of the material layer in a region covered by the gate electrode to form an inversion layer, thereby forming a conductive channel. Such a structure has an advantage of achieving a higher integration density, but has a disadvantage that the high-frequency response capability associated with the two-dimensional carrier gas channel of the HEMT device is lost. In addition, because threshold voltage also needs to be taken into consideration, a thickness of the insulation layer cannot be excessively large. As a result, a gate region at a bottom portion in a vertical direction is susceptible to reliability issues such as breakdown after long-term exposure to an electric field from the drain electrode. Existing silicon (Si)-based and silicon carbide (SiC)-based power devices include various structures for enhancing breakdown protection of a vertical gate, but such structures require formation of a protection region at a bottom portion of the vertical gate through complicated combined ion implantation processes. The fabrication difficulty is relatively high, and such structures are not suitable for HEMT device structures formed of GaN materials or the like.

Accordingly, there is an urgent need to provide a high breakdown voltage HEMT device capable of improving breakdown voltage characteristics of HEMT devices.

### SUMMARY

In order to solve the above-described problems existing in the related art, the disclosure provides a high breakdown voltage HEMT device and a driving method thereof. The technical problems to be solved by the disclosure are achieved through the following technical solutions.

In a first aspect, the disclosure provides a high breakdown voltage HEMT device, including:
a multilayer body material layer;
a source electrode and a drain electrode, wherein the source electrode and the drain electrode are both stacked with the multilayer body material layer; along a first direction, the source electrode and the drain electrode are respectively located on two opposite sides of the multilayer body material layer; or, along the first direction, the source electrode and the drain electrode are located on a same side of the multilayer body material layer, and the source electrode and the drain electrode are respectively located on different mesas;
a first gate electrode, wherein the first gate electrode is located on the same side of the multilayer body material layer as the source electrode and is stacked with the multilayer body material layer; and the first gate electrode is disposed adjacent to the source electrode; and
a second gate electrode, wherein the second gate electrode is located on the same side of the multilayer body material layer as the first gate electrode, the second gate electrode is disposed adjacent to the first gate electrode, and the first gate electrode is located between the second gate electrode and the source electrode; the second gate electrode extends from a surface of the multilayer body material layer into an interior of the multilayer body material layer and extends along the first direction, and the second gate electrode is configured to control a vertical conductive channel along the first direction; and the first direction is perpendicular to the multilayer body material layer.

In a second aspect, the disclosure further provides a driving method of a high breakdown voltage HEMT device, including:
applying a first voltage to the second gate electrode, wherein the applied first voltage is greater than a first threshold value; turning on a vertical conductive channel, adjusting a current conduction capability of the vertical conductive channel by adjusting a magnitude of the first voltage; controlling the first gate electrode by an external driving signal, applying a second voltage to the first gate electrode, such that when the applied second voltage reaches a second threshold value, a horizontal two-dimensional carrier gas channel under the first gate electrode is controlled by the first gate electrode to be turned on or turned off, whereby after the second gate electrode turns on the vertical conductive channel, turning on and turning off the HEMT device controlled by the external driving signal applied to the first gate electrode; and
applying a positive voltage, a zero bias voltage, or a negative voltage to the second gate electrode, wherein each of the positive voltage, the zero bias voltage, and the negative voltage is less than the first threshold value, such that a condition for turning on the vertical conductive channel is not satisfied, and controlling, the first gate electrode, turning on or turning off of a two-dimensional carrier gas conductive channel under an action of an external driving signal, while the HEMT device as a whole remains in an off state.

Beneficial effects of the disclosure are as follows.

According to the high breakdown voltage HEMT device and the driving method thereof provided by the disclosure, the first gate electrode is stacked on the surface of the multilayer body material layer, and the second gate electrode extends from the surface of the multilayer body material layer into the interior of the multilayer body material layer and further extends along the direction perpendicular to the multilayer body material layer. A two-dimensional carrier gas channel is formed below a portion of the HEMT device covered by the first gate electrode, while no two-dimensional carrier gas channel is formed below a portion of the HEMT device covered by the second gate electrode. When a sufficient voltage is applied to the second gate electrode, a vertical conductive channel is formed below the portion of the HEMT device covered by the second gate electrode. At this time, the two-dimensional carrier gas channel and the vertical conductive channel form an electrically connected conduction path. In addition, by adjusting the voltage applied to the second gate electrode, an on-resistance of the vertical conductive channel extending in a direction perpendicular to the multilayer body material layer can also be adjusted. Accordingly, by applying an operating voltage to the second gate electrode before operation of the device, a conductive channel in the vertical direction of the device is established in advance. At the same time, current can be guided into the interior of the HEMT device through the second gate electrode extending in the vertical direction of the device, thereby achieving the purpose of utilizing the multilayer body material layer to improve breakdown voltage of the device. Subsequently, by applying a control signal to the first gate electrode, conduction or cut-off between the source electrode and the drain electrode of the HEMT device can be controlled. In this manner, excellent high-frequency response capability and low on-resistance associated with controlling conduction and cut-off of the two-dimensional carrier gas channel through the first gate electrode can be retained. In addition, through the inversion channel layer connected to the source electrode, breakdown voltage applied to the first gate electrode is mainly borne by a drift region, thereby ensuring breakdown voltage performance of the device while obtaining operating frequency characteristics of the HEMT device and improving current density of the HEMT device.

The disclosure will be further described in detail below with reference to the accompanying drawings and embodiments.

### BRIEF DESCRIPTION OF DRAWINGS

FIG. 1 is a schematic diagram of a high breakdown voltage HEMT device according to an embodiment of the disclosure.

FIG. 2 is another schematic diagram of the high breakdown voltage HEMT device according to an embodiment of the disclosure.

FIG. 3 is another schematic diagram of the high breakdown voltage HEMT device according to an embodiment of the disclosure.

FIG. 4 is a top view of the high breakdown voltage HEMT device according to an embodiment of the disclosure.

FIG. 5 is a schematic diagram of a first gate electrode according to an embodiment of the disclosure.

FIG. 6 is another schematic diagram of the high breakdown voltage HEMT device according to an embodiment of the disclosure.

FIG. 7 is another schematic diagram of the high breakdown voltage HEMT device according to an embodiment of the disclosure.

FIG. 8 is another schematic diagram of the high breakdown voltage HEMT device according to an embodiment of the disclosure.

FIG. 9 is another schematic diagram of the high breakdown voltage HEMT device according to an embodiment of the disclosure.

FIG. 10 is another schematic diagram of the high breakdown voltage HEMT device according to an embodiment of the disclosure.

FIG. 11 is another schematic diagram of the high breakdown voltage HEMT device according to an embodiment of the disclosure.

FIG. 12 is another schematic diagram of the high breakdown voltage HEMT device according to an embodiment of the disclosure.

FIG. 13 is another top view of the high breakdown voltage HEMT device according to an embodiment of the disclosure.

FIG. 14 is another top view of the high breakdown voltage HEMT device according to an embodiment of the disclosure.

FIG. 15 is another schematic diagram of the high breakdown voltage HEMT device according to an embodiment of the disclosure.

FIG. 16 is another top view of the high breakdown voltage HEMT device according to an embodiment of the disclosure.

### DETAILED DESCRIPTION OF EMBODIMENTS

The disclosure will be further described in detail below with reference to specific embodiments. However, the embodiments of the disclosure are not limited thereto.

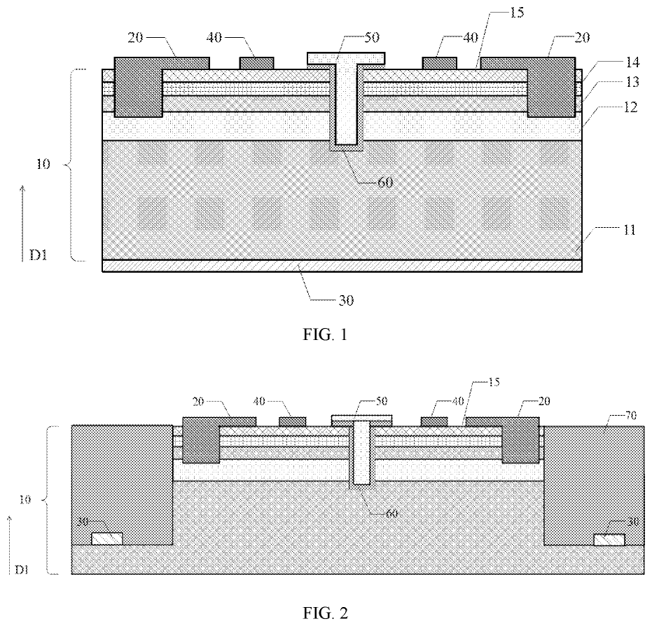

Referring to FIGS. 1 and 2, FIG. 1 is a schematic diagram of a high-breakdown-voltage HEMT device according to an embodiment of the disclosure, and FIG. 2 is another schematic diagram of the high-breakdown-voltage HEMT device according to the embodiment of the disclosure. The high-breakdown-voltage HEMT device provided in the disclosure includes: a multilayer body material layer 10, a source electrode 20, a drain electrode 30, a first gate electrode 40, and a second gate electrode 50.

The source electrode 20 and the drain electrode 30 are both stacked with the multilayer body material layer 10; along a first direction D1, the source electrode 20 and the drain electrode 30 are respectively located on opposite sides of the multilayer body material layer 10. Alternatively, along the first direction D1, the source electrode 20 and the drain electrode 30 are located on the same side of the multilayer body material layer 10, and the source electrode 20 and the drain electrode 30 are respectively located on different mesas 70.

The first gate electrode 40 and the source electrode 20 are located on the same side of the multilayer body material layer 10 and are stacked with the multilayer body material layer 10; the first gate electrode 40 is disposed adjacent to the source electrode 20 and may be spaced apart therefrom.

The second gate electrode 50 and the first gate electrode 40 are located on the same side of the multilayer body material layer 10, the second gate electrode 50 is disposed adjacent to the first gate electrode 40 and may be spaced apart therefrom, and the first gate electrode 40 is located between the second gate electrode 50 and the source electrode 20. The second gate electrode 50 extends from a surface of the multilayer body material layer 10 into the interior of the multilayer body material layer 10 and extends along the first direction D1, and the second gate electrode 50 is configured to control a vertical conductive channel along the first direction D1. The first direction D1 is perpendicular to the multilayer body material layer 10.

Specifically, with continued reference to FIGS. 1 and 2, the high-breakdown-voltage HEMT device provided in the present embodiment includes the multilayer body material layer 10, the source electrode 20, the drain electrode 30, the first gate electrode 40, and the second gate electrode 50. The source electrode 20 and the drain electrode 30 are both stacked with the multilayer body material layer 10. Along the first direction D1, i.e., in a direction perpendicular to the multilayer body material layer, the source electrode 20 and the drain electrode 30 are respectively located on opposite sides of the multilayer body material layer 10, as shown in FIG. 1. Alternatively, along the first direction D1, the source electrode 20 and the drain electrode 30 are located on the same side of the multilayer body material layer 10 and are respectively located on different mesas 70, as shown in FIG. 2. The first gate electrode 40 and the second gate electrode 50 are both located on the same side of the multilayer body material layer 10, and the first gate electrode 40 and the second gate electrode 50 are located on the same side as the source electrode 20. The first gate electrode 40 is disposed adjacent to the source electrode 20 and may be spaced apart therefrom. The second gate electrode 50 is disposed adjacent to the first gate electrode 40 and may be spaced apart therefrom, and the first gate electrode 40 is located between the second gate electrode 50 and the source electrode 20. The first gate electrode 40 is only stacked on the surface of the multilayer body material layer 10, whereas the second gate electrode 50 extends from the surface of the multilayer body material layer 10 into the interior of the multilayer body material layer 10 and extends in a direction perpendicular to the multilayer body material layer 10. Optionally, the first gate electrode 40 may be a p-type GaN gate electrode, a metal gate electrode, or a metal recessed gate electrode, and the second gate electrode 50 may be made of metal. It should be understood that a two-dimensional carrier gas channel is formed beneath the portion of the HEMT device covered by the first gate electrode 40, whereas no two-dimensional carrier gas channel is formed beneath the portion of the HEMT device covered by the second gate electrode 50. When a sufficient voltage is applied to the second gate electrode 50, a vertically extending conductive channel is formed beneath the portion of the HEMT device covered by the second gate electrode 50. At this time, the two-dimensional carrier gas channel and the vertically extending conductive channel form an electrically connected conduction path. In this manner, by applying an operating voltage to the second gate electrode 50 before operation of the device, a vertical conduction path of the device is established in advance. Thereafter, by applying a control signal to the first gate electrode 40, conduction or cutoff between the source electrode 20 and the drain electrode 30 of the HEMT device may be controlled. Thus, the excellent high-frequency response capability associated with controlling conduction and cutoff of the two-dimensional carrier gas through the first gate electrode 40 can be retained. Meanwhile, current can be guided into the interior of the HEMT device through the vertically extending second gate electrode 50, thereby achieving improved breakdown voltage capability by utilizing the multilayer body material layer 10, while also maintaining the operating frequency performance of the HEMT device.

It should be noted that the first gate electrode 40 for controlling conduction and cutoff of the two-dimensional carrier gas channel may be a normally-on gate electrode, in which the two-dimensional carrier gas channel remains conductive when no gate voltage is applied to the first gate electrode 40, and the two-dimensional carrier gas channel can only be turned off by applying a voltage to the first gate electrode 40. Alternatively, the first gate electrode 40 may be a normally-off gate electrode, in which the two-dimensional carrier gas channel remains off when no gate voltage is applied to the first gate electrode 40, and the two-dimensional carrier gas channel can only be turned on by applying a voltage to the first gate electrode 40.

The two-dimensional carrier gas may be a two-dimensional electron gas or a two-dimensional hole gas. In the case of a two-dimensional electron gas channel beneath a normally-on gate electrode, a negative voltage needs to be applied to the gate electrode to turn off the channel. In the case of a two-dimensional electron gas channel beneath a normally-off gate electrode, a positive voltage needs to be applied to the gate electrode to turn on the channel. In the case of a two-dimensional hole gas channel beneath a normally-on gate electrode, a positive voltage needs to be applied to the gate electrode to turn off the channel. In the case of a two-dimensional hole gas channel beneath a normally-off gate, a negative voltage needs to be applied to the gate electrode to turn on the channel. When the employed two-dimensional carrier gas is a two-dimensional electron gas, the inversion channel layer 12 in the multilayer body material structure is generally formed of p-type doped GaN material. When the employed two-dimensional carrier gas is a two-dimensional hole gas, the inversion channel layer 12 in the multilayer body material structure is generally formed of n-type doped GaN material.

It should be understood that the barrier layer 14 is generally formed of aluminum gallium nitride (AlGaN) material, although other GaN-based materials may also be used. The polarization channel layer 13 is generally formed of GaN material, although other GaN-based materials may also be used. When the bandgap width of the material of the barrier layer 14 is greater than the bandgap width of the material of the polarization channel layer 13, a two-dimensional electron gas is formed on a side of the polarization channel layer 13 adjacent to the barrier layer 14. When the bandgap width of the material of the barrier layer 14 is smaller than the bandgap width of the material of the polarization channel layer 13, a two-dimensional hole gas is formed on the side of the polarization channel layer 13 adjacent to the barrier layer 14.

The GaN-based materials mainly include GaN, BN, and alloy materials represented by AlₓGa_{y}In_{1-x-y}N (0≤x≤1, 0≤y≤1, 0≤x+y≤1).

It should be noted that the embodiment shown in FIG. 1 merely schematically illustrates the positional relationship among the multilayer body material layer 10, the first gate electrode 40, and the second gate electrode 50, and further illustrates that the source electrode 20 and the drain electrode 30 are located on different sides of the multilayer body material layer 10, and does not represent actual dimensions thereof. The embodiment shown in FIG. 2 merely schematically illustrates the positional relationship among the multilayer body material layer 10, the first gate electrode 40, and the second gate electrode 50, and further illustrates that the source electrode 20 and the drain electrode 30 are located on the same side of the multilayer body material layer 10 and on different mesas, and does not represent actual dimensions thereof.

In an optional embodiment of the disclosure, the multilayer body material layer 10 includes a drift layer 11, an inversion channel layer 12, a polarization channel layer 13, and a barrier layer 14 sequentially stacked in that order. The drain electrode 30 is located on a side of the drift layer 11 facing away from the inversion channel layer 12, and the source electrode 20 is located on a side of the barrier layer 14 facing away from the polarization channel layer 13. A two-dimensional carrier gas conductive channel is formed between the polarization channel layer 13 and the barrier layer 14, and the first gate electrode 40 is configured to control the two-dimensional carrier gas conductive channel.

Specifically, referring to FIG. 1, in the present embodiment, the multilayer body material layer 10 includes the drift layer 11, the inversion channel layer 12, the polarization channel layer 13, and the barrier layer 14 stacked in that order. The drift layer 11 is an n-type drift layer 11. As shown in FIG. 1, a cap layer 15 is disposed above the barrier layer 14, and the source electrode 20, the first gate electrode 40, and the second gate electrode 50 are all disposed above the cap layer 15 and stacked with the cap layer 15, while the drain electrode 30 is located below the drift layer 11.

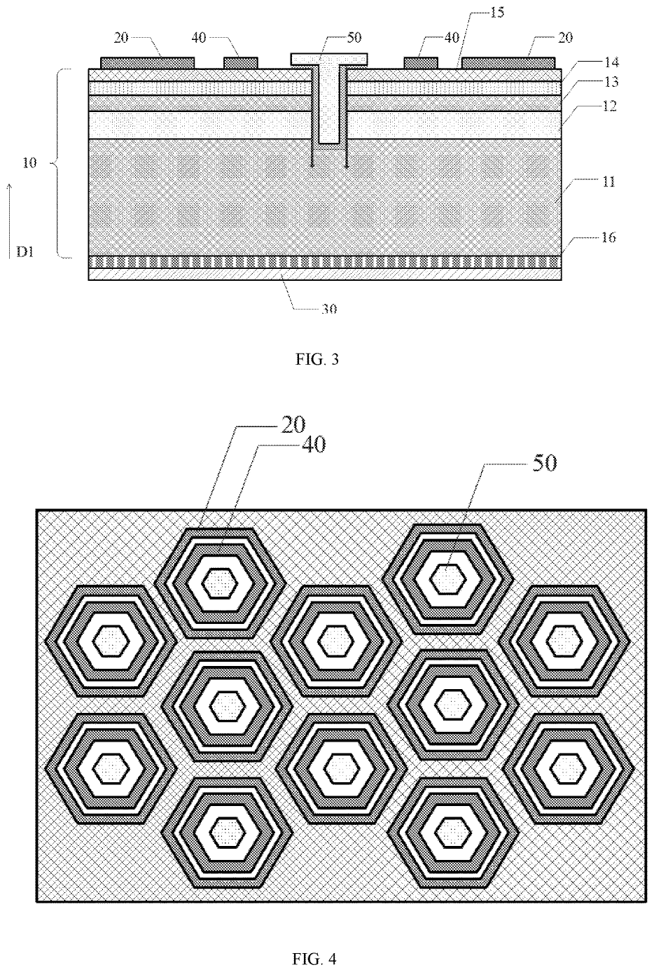

In an optional embodiment of the disclosure, referring to FIGS. 3 and 4, FIG. 3 is another schematic diagram of the high-breakdown-voltage HEMT device provided in an embodiment of the disclosure, and FIG. 4 is a top view of the high-breakdown-voltage HEMT device provided in an embodiment of the disclosure. An n+electrode contact layer 16 is disposed below the n-type drift layer 11, and the drain electrode 30 is disposed below the n+ electrode contact layer 16. The n+ electrode contact layer 16 is stacked with the drain electrode 30. An n-type heavily doped metal contact layer is disposed between the drift layer 11 and the metal of the drain electrode 30, mainly for reducing the metal-semiconductor contact resistance. The drift layer 11 is generally an n-type lightly doped material layer or an unintentionally doped material layer, and mainly functions to withstand the voltage of the drain electrode 30 when the device is in an off state. As shown in FIG. 4, the first gate electrode 40 surrounds the second gate electrode 50, and the source electrode 20 surrounds the first gate electrode 40. FIG. 4 merely schematically illustrates the electrodes as having polygonal shapes. The electrodes may also have circular or elliptical shapes. The shapes of the electrodes are not limited herein and may be determined according to actual requirements.

It should be noted that the multilayer body material layer 10 may include the cap layer 15, the barrier layer 14, the polarization channel layer 13, and the drift layer 11 stacked in that order, or may include the cap layer 15, the barrier layer 14, the polarization channel layer 13, the inversion channel layer 12, and the drift layer 11 stacked in that order. The film layers included in the multilayer body material layer 10 are not limited herein and may be determined according to actual requirements.

It should further be noted that, with continued reference to FIG. 4, the HEMT device may be composed of unit cells having a structure in which the first gate electrode 40 surrounds the second gate electrode 50 and the source electrode 20 surrounds the first gate electrode 40. Electrical isolation between adjacent unit cells may further be achieved through insulation mesas. The concept of the unit cell is consistent with that used in existing power devices such as insulated gate bipolar transistors (IGBTs) and vertical power silicon metal-oxide-semiconductor field-effect transistors (Si MOSFETs), and thus will not be separately described herein. It should also be noted that, in the present embodiment, the multilayer body material layer 10 includes at least one two-dimensional carrier gas channel. When one two-dimensional carrier gas channel is included, the multilayer body material layer 10 includes one polarization channel layer 13 and one barrier layer 14 stacked in that order to form one two-dimensional carrier gas channel. When multiple two-dimensional carrier gas channels are included, the multilayer body material layer 10 includes multiple channel layers 13 and multiple barrier layers 14 alternately stacked in that order, in which one polarization channel layer 13 and one barrier layer 14 form one two-dimensional carrier gas channel, thereby forming multiple two-dimensional carrier gas channels. When multiple two-dimensional carrier gas channels are included, the first gate electrode 40 can control the multiple two-dimensional carrier gas channels.

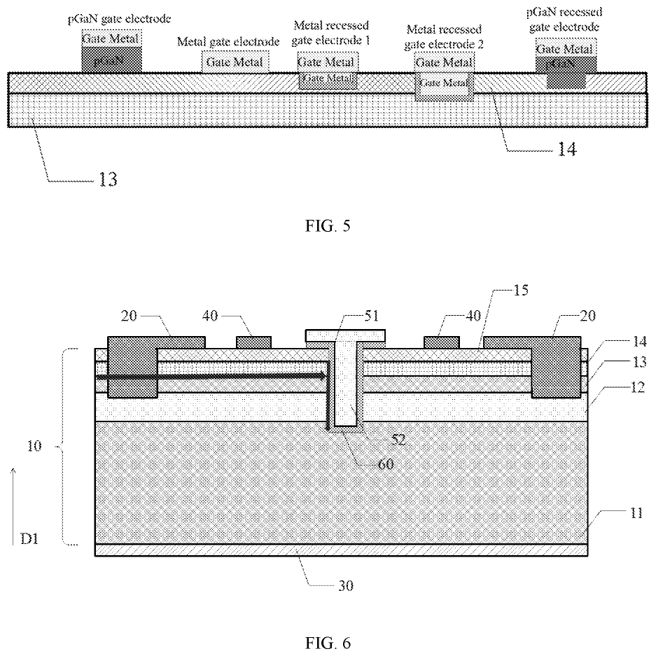

In an optional embodiment of the disclosure, referring to FIG. 5, FIG. 5 is a schematic diagram of the first gate electrode 40 according to an embodiment of the disclosure. The first gate electrode 40 may be any one of a pGaN gate electrode, a metal gate electrode, a metal recessed gate electrode 1, a metal recessed gate electrode 2, or a pGaN recessed gate electrode. Specific structures thereof may be referred to FIG. 5.

In an optional embodiment of the disclosure, the multilayer body material layer 10 is sequentially grown layer by layer through epitaxy in a single epitaxial process.

Specifically, in the present embodiment, the multilayer body material layer 10 is sequentially grown layer by layer through epitaxy in a single epitaxial process. In this manner, the fabrication process can be simplified and process steps can be reduced.

In an optional embodiment of the disclosure, referring to FIG. 6, FIG. 6 is another schematic diagram of the high-breakdown-voltage HEMT device provided in an embodiment of the disclosure. The second gate electrode 50 includes a first portion 51 and a second portion 52. The first portion 51 is stacked with the multilayer body material layer 10, and the second portion 52 extends from the surface of the multilayer body material layer 10 to the drift layer 11. An insulation layer 60 is disposed at the contact interface between the second portion 52 and the multilayer body material layer 10.

Specifically, with continued reference to FIGS. 1 and 3 in combination with FIG. 6, in the present embodiment, the second gate electrode 50 includes two portions, namely the first portion 51 and the second portion 52. The first portion 51 is disposed above the cap layer 15, and the second portion 52 extends from the upper surface of the cap layer 15 to the drift layer 11. It should be understood that the insulation layer 60 is disposed at contact interfaces between side surfaces of the second portion 52 and the cap layer 15, the barrier layer 14, the polarization channel layer 13, the inversion channel layer 12, and the drift layer 11.

In the present embodiment, with continued reference to FIG. 6, the first gate electrode 40 controls the two-dimensional carrier gas channel formed between the barrier layer 14 and the polarization channel layer 13, and the second gate electrode 50 controls a vertical channel extending through the barrier layer 14 and the polarization channel layer 13, or through the barrier layer 14, the polarization channel layer 13, and the inversion channel layer 12 to the drift layer 11. When a forward voltage is applied to the second gate electrode 50, electron accumulation occurs at sidewalls of the second portion 52. Furthermore, when the voltage applied to the second gate electrode 50 is sufficiently large, electron accumulation begins to occur in the material of the polarization channel layer 13 and the inversion channel layer adjacent to sidewalls of the second gate electrode 50 near the polarization channel layer 13 and the inversion channel layer 12, eventually forming a conductive channel. As shown in FIG. 6, the horizontal arrows represent the two-dimensional carrier gas channel formed beneath the portion of the HEMT device covered by the first gate electrode 40, and the vertical arrows represent the vertically extending conductive channel formed beneath the portion of the HEMT device covered by the second gate electrode 50 when a sufficient voltage is applied to the second gate electrode 50. At this time, the two-dimensional carrier gas formed between the barrier layer 14 and the polarization channel layer 13 forms an electrically conductive path with the drift layer 11 through the channel formed by the second gate electrode 50. A side of the drift layer 11 facing away from the polarization channel layer 13 and/or the inversion channel layer 12 is connected to the drain electrode 30 of the HEMT device. Whether a conductive path exists between the source electrode 20 and the drain electrode 30 of the HEMT device is controlled by the state of the first gate electrode 40. When the first gate electrode 40 turns on the two-dimensional carrier gas channel, the source electrode 20 and the drain electrode 30 of the HEMT device are conducted through the two-dimensional carrier gas channel and the conductive channel formed by the second gate electrode 50. The voltage drop from the drain electrode 30 to the source electrode 20 is mainly distributed in the portion where the second gate electrode 50 extends into the drift layer 11, or in the portion including the inversion channel layer 12 and the portion where the second gate electrode 50 extends into the drift layer 11.

In the present embodiment, by applying an operating voltage to the second gate electrode 50 before operation of the device, a vertically extending conductive channel of the HEMT device is established in advance, and then the conduction or cutoff between the source electrode 20 and the drain electrode 30 of the HEMT device is controlled through the first gate electrode 40 and the control signal applied thereto. In this way, the excellent high-frequency response capability achieved by controlling conduction and cutoff of the two-dimensional carrier gas through the first gate electrode 40 can be retained, thereby improving the operating frequency of the device while ensuring HEMT device performance. Meanwhile, current can be guided into the interior of the device through the vertically extending second gate electrode 50, thereby utilizing the material of the multilayer body material layer 10 to improve the breakdown voltage capability of the HEMT device. Since the voltage applied to the second gate electrode 50 is not limited by the driving voltage, an appropriate voltage may be applied as needed to reduce the on-resistance of the vertical channel, such that the HEMT device structure proposed in the disclosure does not increase the overall on-resistance. Furthermore, the insulation layer 60 disposed outside the second portion 52 of the second gate electrode 50 may also employ a relatively thick insulation material. The thickness of the insulation layer 60 is not limited herein, and can better withstand the voltage of the drain electrode 30 when the HEMT device is in the off state. When the HEMT device is not operating, no voltage may be applied to the second gate electrode 50, such that excessive electric field stress due to a voltage difference between the second gate electrode 50 and the first gate electrode 40 can be avoided, thereby preventing reliability issues such as dynamic on-resistance drift or current collapse caused by the influence of the drain voltage on the first gate electrode 40 in conventional HEMT devices. Furthermore, a field plate may be additionally provided on the first gate electrode 40 and/or the source electrode 20 to further reduce the influence of the voltage applied to the second gate electrode 50 on the first gate electrode 40. Field plates for the first gate electrode 40 and the source electrode 20 are relatively common structures in HEMT fabrication and therefore will not be separately described herein.

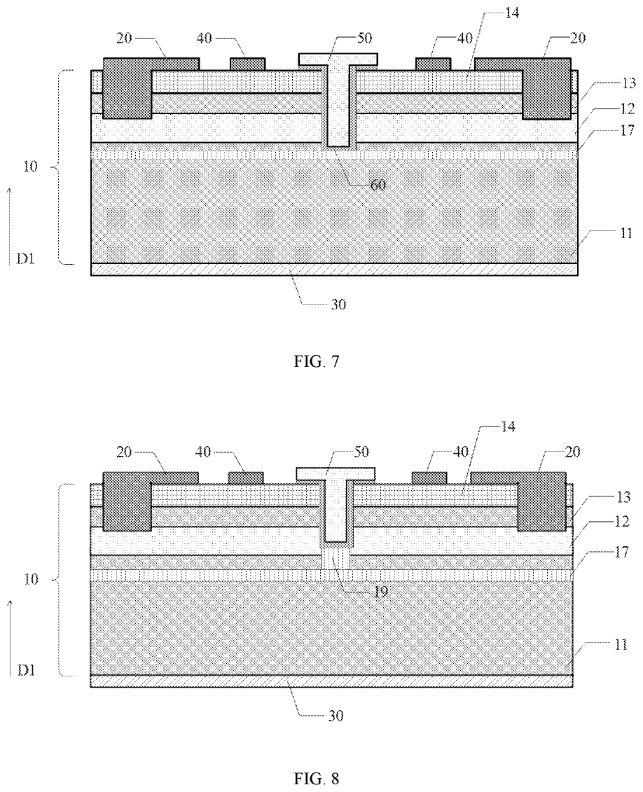

In an optional embodiment of the disclosure, referring to FIG. 7, FIG. 7 is another schematic diagram of the high-breakdown-voltage HEMT device provided in an embodiment of the disclosure. The device further includes at least one diffusion layer 17. The diffusion layer 17 is located in the drift layer 11, and the diffusion layer 17 is located on a side of the second portion 52 facing away from the first portion 51. The diffusion layer 17 is in contact with the insulation layer 60 disposed outside the second portion 52.

Specifically, with continued reference to FIG. 7, in the present embodiment, in order to further enhance performance of the HEMT device, the layer structure of the HEMT device further includes the diffusion layer 17. The diffusion layer 17 is an n-type heavily doped diffusion layer 17 located within the drift layer 11 and below the polarization channel layer 13 or below the polarization channel layer 13 and the inversion channel layer 12. The insulation layer 60 disposed outside the second portion 52 of the second gate electrode 50 is in contact with the n-type heavily doped diffusion layer 17. It should be understood that no inversion channel layer 12 is present below the diffusion layer 17. Carriers entering the drift layer 11 through the channel generated by the second gate electrode 50 are further current-spread within the diffusion layer 17, thereby facilitating more uniform current distribution in the HEMT device.

It should be noted that the embodiment shown in FIG. 7 merely schematically illustrates an example in which one diffusion layer 17 is provided, and does not represent the actual dimensions thereof.

In an optional embodiment of the disclosure, referring to FIG. 8, FIG. 8 is another schematic diagram of the high-breakdown-voltage HEMT device provided in the embodiment of the disclosure. The second gate electrode 50 includes a first portion 51 and a second portion 52. The first portion 51 is located above the multilayer body material layer 10, and an insulation layer 60 is disposed between the first portion 51 and the multilayer body material layer. The second portion 52 extends from the surface of the multilayer body material layer 10 to the inversion channel layer 12, and the insulation layer 60 is disposed at the contact interface between the second portion 52 and the multilayer body material layer 10.

In an optional embodiment of the disclosure, an n-type region 19 is disposed between the drift layer 11 and the second portion 52. Along the first direction D1, a portion of the n-type region 19 passes through the inversion channel layer 12, one side of the n-type region 19 contacts the insulation layer 60 outside the second portion 52, and the other side of the n-type region 19 contacts the drift layer 11.

Specifically, continuing to refer to FIG. 8, in the present embodiment, the second portion 52 of the second gate electrode 50 extends to the inversion channel layer 12. Ions are implanted between the insulation layer 60 outside the bottom of the second portion 52 and the diffusion layer 17, thereby forming the n-type region 19 therebetween. It can be understood that, in order to better disperse the electric field applied by the drain electrode 30 to the bottom of the second gate electrode 50, the bottom of the second gate electrode 50 is designed within the inversion channel layer 12. After etching a vertical channel during fabrication of the second gate electrode 50, ion implantation is performed at the bottom of the channel so as to modify the inversion channel layer 12 at the bottom of the channel into the n-type region 19 (i.e., the inversion channel layer 12 is converted into the n-type region 19). The n-type region 19 is in direct contact with the drift layer 11. After the insulation layer 60 and gate metal of the second gate electrode 50 are subsequently formed, a JFET structure in which the inversion channel layer 12 surrounds the n-type material is formed at the bottom of the second gate electrode 50. The inversion channel layer 12 effectively surrounds the front edge at the bottom of the second gate electrode 50, and when the HEMT device is in the off state, the voltage of the drain electrode 30 acts on the n-type material surrounded by the inversion channel layer 12, thereby forming a reverse-biased PN junction with the inversion channel layer, which further protects the bottom of the second gate electrode 50.

In the present embodiment, after etching the multilayer body material layer 10 to form a hole for the second gate electrode 50, n-type GaN material is regrown by secondary epitaxy. Thereafter, a portion of the n-type GaN material is removed by etching while retaining the n-type GaN material at the bottom of the hole. Subsequently, the insulation layer and metal are deposited within the hole region to form the second gate electrode 50. At this time, the n-type region 19 at the bottom of the second gate electrode 50 is the retained n-type GaN material at the bottom of the hole.

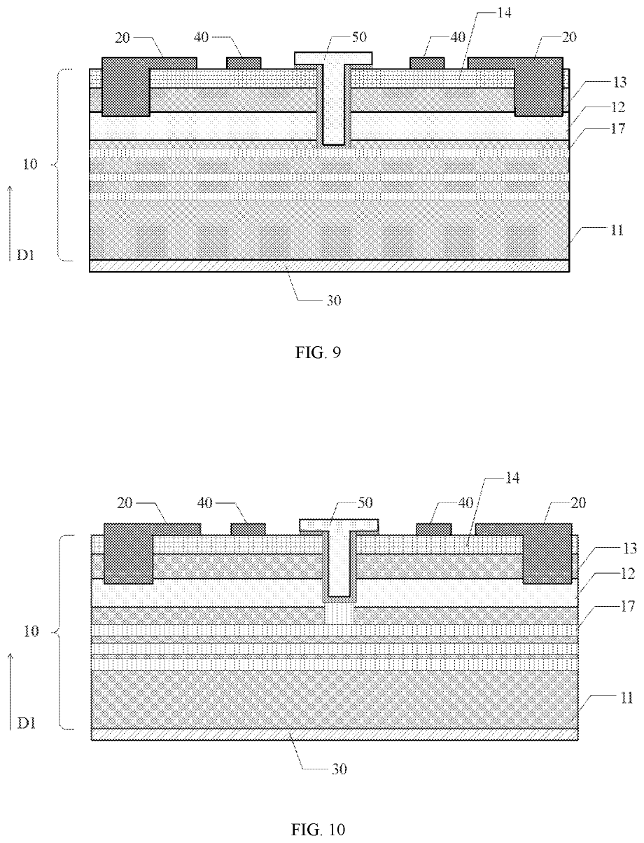

In an optional embodiment of the disclosure, referring to FIG. 9 and FIG. 10, FIG. 9 is another schematic diagram of the high-breakdown-voltage HEMT device provided in the embodiment of the disclosure, and FIG. 10 is another schematic diagram of the high-breakdown-voltage HEMT device provided in the embodiment of the disclosure. The diffusion layer 17 includes multiple layers, all of which are located within the drift layer 11 and are spaced apart from each other. Among the multiple diffusion layers 17, the diffusion layer 17 adjacent to the second portion 52 contacts the insulation layer 60 outside the second portion 52. Alternatively, among the multiple diffusion layers 17, an n-type region 19 is disposed between the diffusion layer 17 adjacent to the second portion 52 and the second portion 52.

Specifically, continuing to refer to FIG. 9 and FIG. 10, in the present embodiment, the diffusion layer 17 may be a single-layer material or a stack of multiple parallel heavily doped n-type material layers. The multiple parallel heavily doped n-type material layers enable current to spread more uniformly, thereby reducing the on-resistance of the device. When the heavily doped n-type diffusion layer 17 is formed as a stack of multiple parallel heavily doped n-type material layers, the bottom of the second gate electrode 50 needs to reach the diffusion layer 17 closest to the inversion channel layer 12 or the drift layer 11 above such diffusion layer 17. Alternatively, within the inversion channel layer 12, the material of the inversion channel layer 12 covered by the bottom of the second gate electrode 50 may be converted into n-type material through the above-described ion implantation method, and the n-type material is connected to the diffusion layer 17 closest to the inversion channel layer 12 or the drift layer 11 above such diffusion layer 17.

It should be noted that the embodiments shown in FIG. 9 and FIG. 10 merely schematically illustrate an example in which three diffusion layers 17 are provided. Other numbers of diffusion layers 17 may also be used, and the disclosure is not limited thereto.

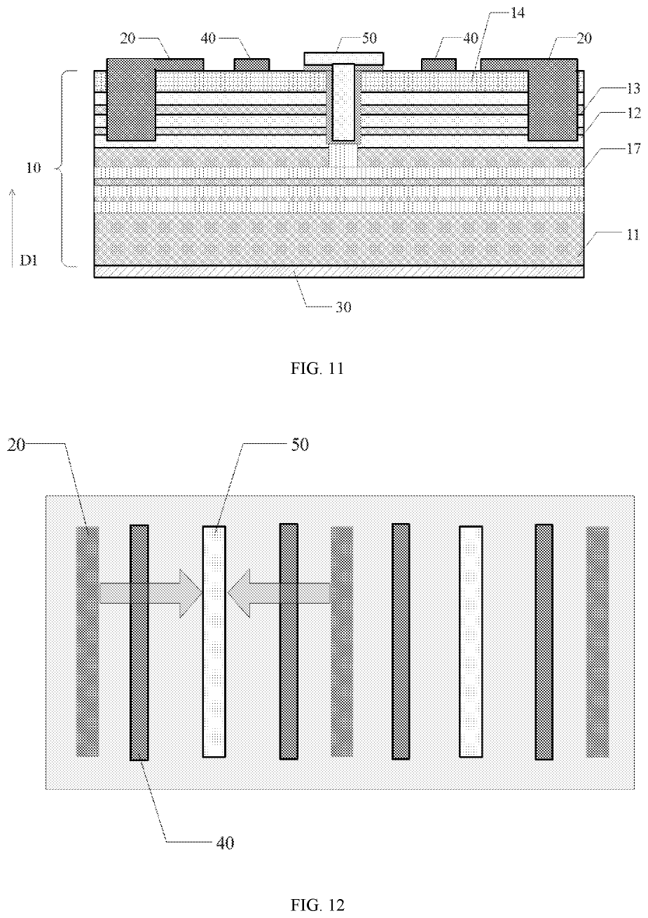

In an optional embodiment of the disclosure, referring to FIG. 11, FIG. 11 is another schematic diagram of the high-breakdown-voltage HEMT device provided in the embodiment of the disclosure. The inversion channel layer 12 includes multiple layers, and adjacent inversion channel layers 12 are spaced apart from each other. The second portion 52 extends through the multiple inversion channel layers 12 to the drift layer 11. Alternatively, the second portion 52 extends through at least a portion of the inversion channel layers 12 to the inversion channel layer 12 adjacent to the drift layer 11.

Specifically, continuing to refer to FIG. 11, in the present embodiment, the inversion channel layer 12 may be a single-layer material or a stack of multiple parallel inversion channel layers. The stacking of multiple inversion channel layers can further reduce device leakage current, improve the breakdown voltage capability of the device, and enhance device reliability. When the inversion channel layer 12 is formed as a stack of multiple parallel inversion channel layers, the bottom of the second gate electrode 50 needs to pass through the last inversion channel layer 12 closest to the diffusion layer 17 and extends into the diffusion layer 17 or the drift layer 11. Alternatively, within the last inversion channel layer 12 closest to the diffusion layer 17, the material of the inversion channel layer 12 covered by the bottom of the second gate electrode 50 may be converted into n-type material through the above-described ion implantation method.

In an optional embodiment of the disclosure, referring to FIG. 1, the source electrode 20 is connected to the two-dimensional carrier gas channel and is also connected to the inversion channel layer 12.

Specifically, continuing to refer to FIG. 1, in the present embodiment, the electrode metal of the source electrode 20 forms an ohmic contact not only with the two-dimensional carrier gas channel but also with the inversion channel layer 12. The ohmic contact between the source electrode 20 and the two-dimensional carrier gas channel is intended to reduce the contact resistance of the source electrode 20, while the ohmic contact with the inversion channel layer 12 is intended to provide a bias voltage from the source electrode 20 to the inversion channel layer 12, thereby preventing the potential of the inversion channel layer 12 from floating, facilitating conduction of the vertical channel, and shielding the effect of the voltage of the drain electrode 30 on the first gate electrode 40. One implementation is to expose the material of the inversion channel layer 12 through mesa etching, such that the metal of the source electrode 20 forms ohmic contact simultaneously with the two-dimensional carrier gas and the inversion channel layer 12 by spanning the mesa.

In an optional embodiment of the disclosure, the drift layer 11 is an n-type drift layer, and the n-type doping concentration in the n-type drift layer 11 is constant.

In an optional embodiment of the disclosure, the drift layer 11 is an n-type drift layer, and the n-type doping concentration in the n-type drift layer 11 is stepwise graded or continuously graded, i.e., in the direction from the source electrode 20 toward the drain electrode 30, the n-type doping concentration of the n-type drift layer 11 may gradually increase or decrease.

In an optional embodiment of the disclosure, the inversion channel layer 12, the diffusion layer 17, and the drift layer 11 include periodic stacked layers of semiconductor materials having different bandgaps. The inversion channel layer 12, the diffusion layer 17, and the drift layer 11 each include at least one semiconductor material.

Specifically, in the present embodiment, the inversion channel layer 12, the heavily doped n-type diffusion layer 17, and the drift layer 11 may each be formed of a single semiconductor material or may be formed by periodically stacking multiple semiconductor materials having different bandgaps. For example, they may include GaN material, or two or more materials selected from GaN, AlGaN, indium gallium nitride (InGaN), indium aluminum gallium nitride (InAlGaN), and the like, stacked alternately. The periodic stacking of semiconductor materials having different bandgaps introduces multiple carrier barriers in the direction in which the multilayer body material layer 10 of the entire HEMT device withstands voltage, thereby helping to further improve breakdown voltage capability and reduce leakage current. In particular, when degradation occurs in the insulation layer 60 of the second gate electrode 50, such structure can help reduce leakage current and thereby extend the service life of the device.

In an optional embodiment of the disclosure, referring to FIG. 12, FIG. 12 is another schematic diagram of the high-breakdown-voltage HEMT device provided in the embodiment of the disclosure. In combination with FIG. 1, along the first direction D1, the source electrode 20 and the drain electrode 30 are disposed on opposite sides of the multilayer body material, and the drain electrode 30 has a planar structure.

Specifically, continuing to refer to FIG. 12 and FIG. 1, in the present embodiment, along the direction perpendicular to the multilayer body material layer 10, the source electrode 20 and the drain electrode 30 are located on opposite sides of the multilayer body material layer 10. The drain electrode 30 is disposed on one side of the drift layer 11 and has a planar structure.

It should be noted that the embodiment shown in FIG. 12 merely schematically illustrates one positional relationship among the first gate electrode 40, the second gate electrode 50, and the source electrode 20 when the source electrode 20 and drain electrode 30 are located on opposite sides.

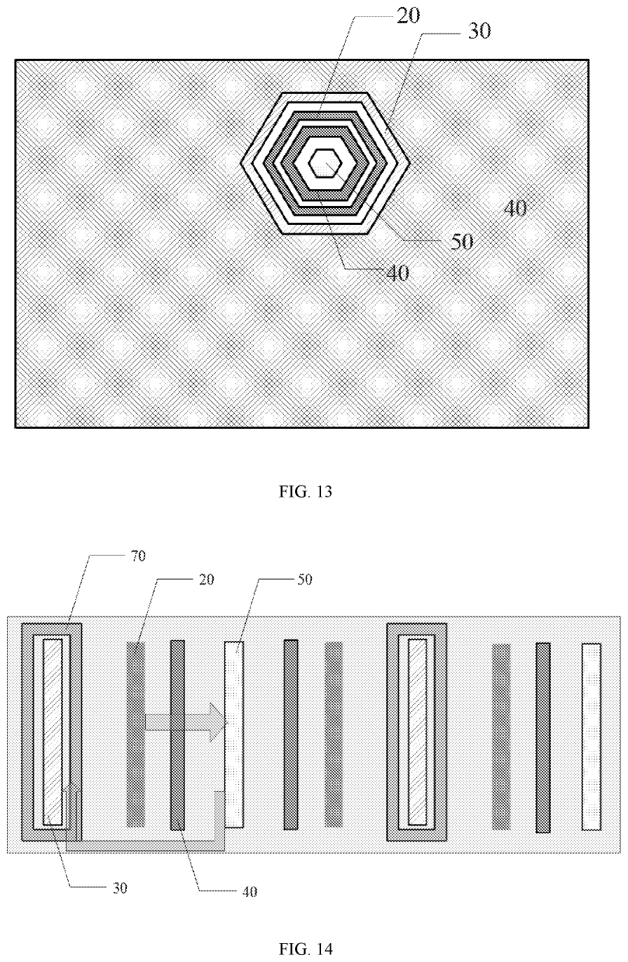

In an optional embodiment of the disclosure, referring to FIG. 13 and FIG. 14 in combination with FIG. 2, FIG. 13 is another top view of the high-breakdown-voltage HEMT device provided in the embodiment of the disclosure, and FIG. 14 is another top view of the high-breakdown-voltage HEMT device provided in the embodiment of the disclosure. Along the first direction D1, the source electrode 20 and the drain electrode 30 are disposed on the same side of the multilayer body material. The drain electrode 30 is disposed adjacent to and spaced apart from the source electrode 20, and the drain electrode 30 extends from the surface of the multilayer body material layer 10 to contact the n-type region 19.

Specifically, continuing to refer to FIG. 13 and FIG. 14 in combination with FIG. 2, in the present embodiment, the source electrode 20 and the first gate electrode 40 are located on the same side but on different mesas 70. The mesa 70 between the source electrode 20 and the drain electrode 30 is isolated by an insulating dielectric. The electric field distribution between the drain electrode 30 and the first gate electrode 40 is shared by the source electrode 20 and the second gate electrode 50. Furthermore, in a structure including the inversion channel layer 12, the electric field is further shared by the inversion channel layer 12 directly contacting the source electrode 20. Therefore, good protection of the first gate electrode 40 can be achieved, thereby ensuring the long-term reliability and stability of the first gate electrode 40.

It should be noted that, in FIG. 14, the short arrows indicate current flow along the current path in the first direction controlled by the first gate, i.e., the two-dimensional carrier gas channel, while the long arrows indicate current flow along the current path of the second gate, i.e., the second direction, and then along a direction parallel to the first direction through the diffusion layer 17 to the current path between the drain electrode 30.

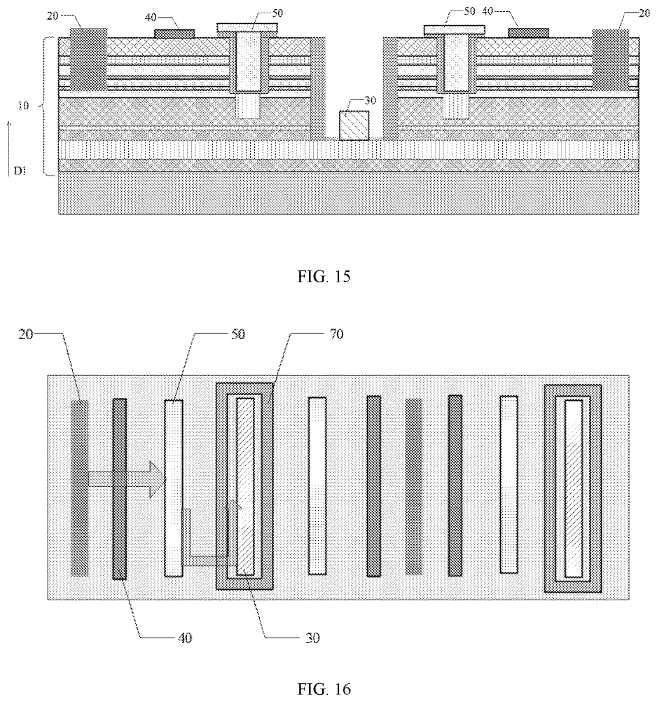

In an optional embodiment of the disclosure, referring to FIG. 15 and FIG. 16, FIG. 15 is another schematic diagram of the high-breakdown-voltage HEMT device provided in the embodiment of the disclosure, and FIG. 16 is another top view of the high-breakdown-voltage HEMT device provided in the embodiment of the disclosure. FIG. 15 illustrates another embodiment in which, along the first direction D1, the source electrode 20 and the drain electrode 30 are disposed on the same side of the multilayer body material, and FIG. 16 is the corresponding top view thereof.

In an optional embodiment of the disclosure, taking a GaN material as an example, the fabrication method of the high breakdown voltage HEMT device proposed in the disclosure is as follows. A relatively thick drift layer 11 is grown on a substrate, and during the growth process of the drift layer 11, the growth of several n-type heavily doped diffusion layers 17 is inserted. Subsequently, after growing the inversion channel layer 12 on the drift layer 11, the polarization channel layer 13 is grown, or alternatively the polarization channel layer 13 is directly grown. A barrier layer 14 is grown above the polarization channel layer 13, followed by the growth of a cap layer 15. If a pGaN gate is adopted, a p-type GaN layer is further grown. Deep holes are etched in the material layers until all inversion channel layers 12 are penetrated, or until the etching stops within the inversion channel layer 12 farthest from the polarization channel layer 13. If the etching stops within the inversion channel layer 12 farthest from the polarization channel layer 13, the material layer surface outside the deep holes needs to be shielded using a mask, and Si ions are implanted into the bottom of the deep holes by ion implantation and subsequently annealed, thereby modifying the inversion channel layer 12 in the bottom region of the deep holes into an n-type region. Thereafter, insulation material is filled into the deep holes.

For the case where the source electrode 20 and the drain electrode 30 are located on opposite sides of the device body material, mesa etching is performed until the inversion channel layer 12 is exposed, and the metal of the source electrode 20 is fabricated on the exposed region of the inversion channel layer 12 and on the surface region of the device material layer adjacent to the mesa so as to form ohmic contact. The fabrication of the first gate electrode 40 includes pGaN etching or groove etching and gate metal deposition. The metal of the second gate electrode 50 needs to be filled onto the insulation material inside the deep holes. A hole space may be reserved during the filling of the insulation material, or alternatively the holes may first be completely filled and then a hole may be etched again inside the insulation material. The metal of the second gate electrode 50 may be filled independently, or may be deposited simultaneously with the metal of the first gate electrode 40. If the substrate at this stage is a GaN homogeneous substrate, the substrate may be thinned from the backside, and metal may be deposited on the side of the device material layer facing away from the source electrode 20 and the first gate electrode 40 to fabricate the drain electrode 30. If the substrate at this stage is a heterogeneous substrate such as Si or sapphire, the substrate may be removed, or the substrate material on the backside may be etched until the drift layer 11 is exposed, after which metal is deposited on the side of the device material layer facing away from the source electrode 20 and the first gate electrode 40 to fabricate the drain electrode 30.

For the case where the source electrode 20 and the drain electrode 30 are located on the same side of the device body material but on different mesas, the fabrication methods of the source electrode 20, the first gate electrode 40, and the second gate electrode 50 are substantially the same. Mesa etching is performed on the side of the source electrode 20 facing away from the first gate electrode 40 until the diffusion layer 17 farthest from the polarization channel layer 13 is exposed. An insulation material is deposited to protect the mesa on the side close to the source electrode 20. The insulation material on the surface of the exposed diffusion layer 17 farthest from the polarization channel layer 13 is etched to form a window for metal deposition, and the metal of the drain electrode 30 is deposited and forms ohmic contact with the n-type diffusion layer, thereby completing the fabrication of the drain electrode 30.

Based on the same inventive concept, the disclosure further provides a driving method of the high breakdown voltage HEMT device, configured to drive the high breakdown voltage HEMT device provided in the foregoing embodiments of the disclosure. Reference may be made to the foregoing embodiments for the high breakdown voltage HEMT device, and repeated descriptions are omitted herein. The driving method includes the steps as follows.

A first positive voltage is applied to the second gate electrode 50, the applied first positive voltage is greater than a first threshold value, such that the vertical conductive channel is turned on, and the current conduction capability of the vertical conductive channel may be adjusted by regulating the magnitude of the first positive voltage. The first gate electrode 40 is controlled by an external driving signal, and a second voltage is applied to the first gate electrode 40. When the applied second voltage reaches a second threshold value, the horizontal two-dimensional carrier gas channel under the first gate electrode 40 is controlled by the first gate electrode 40 to be turned on or off, namely, after the second gate electrode 50 turns on the vertical conductive channel, the turn-on and turn-off of the high breakdown voltage HEMT device are controlled by the external driving signal applied to the first gate electrode 40.

When a positive voltage, a zero bias voltage, or a negative voltage is applied to the second gate electrode 50, the applied positive voltage, zero bias voltage, or negative voltage is less than the first threshold value, such that the condition for turning on the vertical conductive channel is not satisfied, and the first gate electrode 40 controls the turn-on or turn-off of the two-dimensional carrier gas conductive channel under the action of the external driving signal, while the high breakdown voltage HEMT device as a whole still remains in an off state.

Specifically, the present embodiment provides the driving method for the high breakdown voltage HEMT device. The two-dimensional carrier gas channel is present below the HEMT device region covered by the first gate electrode 40, whereas no two-dimensional carrier gas channel is present below the HEMT device region covered by the second gate electrode 50. When a sufficient voltage is applied to the second gate electrode 50, a conductive channel is formed below the HEMT device region covered by the second gate electrode 50. At this time, the two-dimensional carrier gas channel and the conductive channel form an electrically connected conduction path. Accordingly, by applying an operating voltage to the second gate electrode 50 before the device operates, a vertical conductive channel of the device is established in advance, and then a control signal is applied to the first gate electrode 40 to control the turn-on or turn-off between the source electrode 20 and the drain electrode 30 of the HEMT device. In this manner, the excellent high-frequency response capability achieved by controlling the turn-on and turn-off of the two-dimensional carrier gas through the first gate electrode 40 can be retained, thereby improving the operating frequency of the HEMT device while ensuring device performance. Meanwhile, the second gate electrode 50 in the vertical direction of the device can guide current into the interior of the device, thereby achieving the purpose of improving the breakdown voltage of the HEMT device by utilizing the multilayer body material layer 10.

It should be noted that, in the disclosure, relational terms such as “first” and “second” are merely used to distinguish one entity or operation from another entity or operation, and do not necessarily require or imply any actual relationship or order between such entities or operations. Furthermore, the terms “comprise,” “include,” or any variations thereof are intended to cover non-exclusive inclusion, such that a process, a method, an article, or a device including a series of elements not only includes those elements, but may also include other elements not expressly listed. Unless otherwise specifically limited, an element defined by the phrase “comprising a/an . . . ” does not exclude the presence of additional identical elements in the process, method, article, or device that includes the element. Terms such as “connected” or “coupled” are not limited to physical or mechanical connections, but may also include electrical connections, whether direct or indirect. Terms such as “upper,” “lower,” “left,” and “right” indicating orientations or positional relationships are based on the orientations or positional relationships shown in the drawings, and are merely for convenience of description of the disclosure and simplification of the description, rather than indicating or implying that the referenced device or element must have a particular orientation, be constructed and operated in a particular orientation, and therefore should not be construed as limiting the disclosure.

In the description of the present specification, references to terms such as “one embodiment,” “some embodiments,” “example,” “specific example,” or “some examples” mean that the particular features or characteristics described in connection with the embodiment or example are included in at least one embodiment or example of the disclosure. In the present specification, schematic representations of the foregoing terms do not necessarily refer to the same embodiment or example. Moreover, the particular features or characteristics described may be combined in any suitable manner in one or more embodiments or examples. In addition, those skilled in the art may combine and integrate different embodiments or examples described in the present specification.

The foregoing content provides further detailed description of the disclosure in conjunction with specific preferred implementation modes, and shall not be construed as limiting the specific implementations of the disclosure to these descriptions. For those skilled in the art to which the disclosure pertains, several simple derivations or substitutions may be made without departing from the inventive concept of the disclosure, and all such derivations or substitutions shall fall within the protection scope of the disclosure.

What is claimed is:

1. A high electron mobility transistor (HEMT) device, comprising:
a multilayer body material layer;
a source electrode and a drain electrode, wherein the source electrode and the drain electrode are both stacked with the multilayer body material layer; along a first direction, the source electrode and the drain electrode are respectively located on two opposite sides of the multilayer body material layer; or, along the first direction, the source electrode and the drain electrode are located on a same side of the multilayer body material layer, and the source electrode and the drain electrode are respectively located on different mesas;
a first gate electrode, wherein the first gate electrode is located on the same side of the multilayer body material layer as the source electrode and is stacked with the multilayer body material layer; and the first gate electrode is disposed adjacent to the source electrode; and
a second gate electrode, wherein the second gate electrode is located on the same side of the multilayer body material layer as the first gate electrode, the second gate electrode is disposed adjacent to the first gate electrode, and the first gate electrode is located between the second gate electrode and the source electrode; the second gate electrode extends from a surface of the multilayer body material layer into an interior of the multilayer body material layer and extends along the first direction, and the second gate electrode is configured to control a vertical conductive channel along the first direction; and the first direction is perpendicular to the multilayer body material layer.

2. The HEMT device as claimed in claim 1, wherein the multilayer body material layer comprises a drift layer, an inversion channel layer, a polarization channel layer, and a barrier layer sequentially stacked in that order; the drain electrode is located on a side of the drift layer facing away from the inversion channel layer, and the source electrode is located on a side of the barrier layer facing away from the polarization channel layer; a two-dimensional carrier gas conductive channel is formed between the polarization channel layer and the barrier layer, and the first gate electrode is configured to control the two-dimensional carrier gas conductive channel.

3. The HEMT device as claimed in claim 2, wherein the multilayer body material layer is sequentially grown layer by layer by epitaxy in a same epitaxial process.

4. The HEMT device as claimed in claim 2, wherein the second gate electrode comprises a first portion and a second portion, the first portion is stacked with the multilayer body material layer, the second portion extends from a surface of the multilayer body material layer to the drift layer, and an insulation layer is disposed on a contact surface between the second portion and the multilayer body material layer.

5. The HEMT device as claimed in claim 4, further comprising:
at least one diffusion layer, located in the drift layer, wherein the at least one diffusion layer is located on a side of the second portion facing away from the first portion.

6. The HEMT device as claimed in claim 2, wherein the second gate electrode comprises a first portion and a second portion, the first portion is located above the multilayer body material layer, an insulation layer is disposed between the first portion and the multilayer body material layer, the second portion extends from a surface of the multilayer body material layer to the inversion channel layer, and the insulation layer is further disposed on a contact surface between the second portion and the multilayer body material layer.

7. The HEMT device as claimed in claim 6, wherein an n-type region is disposed between the drift layer and the second portion; along the first direction, a portion of the n-type region passes through the inversion channel layer; a side of the n-type region is in contact with the insulation layer outside the second portion, and another side of the n-type region is in contact with the drift layer.

8. The HEMT device as claimed in claim 5, wherein the at least one diffusion layer is multiple in quantity, all of the multiple diffusion layers are located in the drift layer and spaced apart from each other; among the multiple diffusion layers, the diffusion layer adjacent to the second portion is in contact with the insulation layer outside the second portion; or, among the multiple diffusion layers, an n-type region is disposed between the diffusion layer adjacent to the second portion and the second portion.

9. The HEMT device as claimed in claim 4, wherein the inversion channel layer is multiple in quantity, the multiple inversion channel layers are spaced apart from each other; the second portion passes through the multiple inversion channel layers and extends to the drift layer; or the second portion passes through at least part of the multiple inversion channel layers and extends to the inversion channel layer adjacent to the drift layer.

10. The HEMT device as claimed in claim 2, wherein the source electrode is connected to the two-dimensional carrier gas conductive channel and connected to the inversion channel layer.

11. The HEMT device as claimed in claim 1, wherein, along the first direction, the source electrode and the drain electrode are disposed on the opposite sides of the multilayer body material layer, and the drain electrode has a planar structure.

12. The HEMT device as claimed in claim 1, wherein, along the first direction, the source electrode and the drain electrode are disposed on the same side of the multilayer body material layer, and the drain electrode is disposed on and in contact with a diffusion layer exposed after the multilayer body material layer is etched.

13. A driving method of the HEMT device as claimed in claim 1, configured to drive the HEMT device, the driving method comprising:
applying a first voltage to the second gate electrode, wherein the applied first voltage is greater than a first threshold value; turning on a vertical conductive channel, adjusting a current conduction capability of the vertical conductive channel by adjusting a magnitude of the first voltage; controlling the first gate electrode by an external driving signal, applying a second voltage to the first gate electrode, such that when the applied second voltage reaches a second threshold value, a horizontal two-dimensional carrier gas channel under the first gate electrode is controlled by the first gate electrode to be turned on or turned off, whereby after the second gate electrode turns on the vertical conductive channel, turning on and turning off the HEMT device controlled by the external driving signal applied to the first gate electrode; and
applying a positive voltage, a zero bias voltage, or a negative voltage to the second gate electrode, wherein each of the positive voltage, the zero bias voltage, and the negative voltage is less than the first threshold value, such that a condition for turning on the vertical conductive channel is not satisfied, and controlling, the first gate electrode, turning on or turning off of a two-dimensional carrier gas conductive channel under an action of an external driving signal, while the HEMT device as a whole remains in an off state.
